(19) United States
(12) Patent Application Publication
(10) Pub. No.: US 2008/0224133 A1
(43) Pub. Date: Sep. 18, 2008

(54) Thin film transistor and organic light-emitting display device having the thin film transistor

(76) Inventors: Jin-seong Park, Suwon-si (KR); Yeon-gon Mo, Suwon-si (KR); Jae-kyeong Jeong, Suwon-si (KR); Jong-han Jeong, Suwon-si (KR); Hyun-soo Shin, Suwon-si (KR); Hun-jung Lee, Suwon-si (KR)

Correspondence Address: ROBERT E. BUSHNELL, 1522 K STREET NW, SUITE 300, WASHINGTON, DC, 20005-1202, US

(21) Appl. No.: 12/076,216

(22) Filed: Mar. 14, 2008

(30) Foreign Application Priority Data
Mar. 14, 2007 (KR) 10-2007-0025062

(51) Int. Cl. H01L 29/22; H01L 21/34

(52) U.S. Cl. 257/43; 438/104; 257/E29.094; 257/E21.46

(57) ABSTRACT

Disclosed is a thin film transistor including a P-type semiconductor layer, and an organic light-emitting display device having the thin film transistor. The present invention provides a thin film transistor including a substrate, a semiconductor layer, and a gate electrode and a source/drain electrode formed on the substrate, wherein the semiconductor layer is composed of P-type ZnO:N layers through a reaction of a mono-nitrogen gas with a zinc precursor, and the ZnO:N layer includes an un-reacted impurity element at a content of 3 at % or less.

### CLAIM OF PRIORITY

This application makes reference to, incorporates the same herein, and claims all benefits accruing under 35 U.S.C. §119 from an application for THIN FILM TRANSISTOR AND ORGANIC LIGHT-EMITTING DISPLAY DEVICE HAVING THE THIN FILM TRANSISTOR earlier filed in the Korean Intellectual Property Office on the 14^{th} of Mar. 2007 and there duly assigned Serial No. 10-2007-0025062.

### BACKGROUND OF THE INVENTION

1. Field of the Invention

The present invention relates to a thin film transistor and an organic light-emitting display device having the thin film transistor, and more particularly to a thin film transistor including a P-type semiconductor layer, and an organic light-emitting display device having the thin film transistor.

2. Description of the Related Art

Generally, a semiconductor layer using amorphous silicon or poly silicon has been widely used as the thin film transistor used in an organic light-emitting display device. However, if a semiconductor layer is formed of the amorphous silicon, it is difficult to use semiconductor layer as a drive circuit of a display panel demanding a high operation speed due to the low mobility. The poly silicon has a high mobility, but should have a separate compensation circuit due to the non-uniform threshold voltage. Also, leakage electric current is caused if the thin film transistor using the amorphous or poly silicon as the semiconductor layer is irradiated with the light, resulting in deteriorating physical properties of the thin film transistor.

Accordingly, there have been ardent attempts to develop an oxide semiconductor in order to solve the above problems. For example, Japanese Patent Publication No. 2004-273614 (published on Sep. 30, 2004) discloses a thin film transistor using an oxide semiconductor as a semiconductor layer, wherein the oxide semiconductor includes ZnO or ZnO-based material.

Hereinafter, the thin film transistor including ZnO as the semiconductor layer will be described in detail. At this time, it is described that the oxide semiconductor including ZnO or ZnO has a band gap of 3.4, and does not absorb the visible light since it has a higher light energy than the visible light region, and therefore the thin film transistor has an effect that a leakage electric current is not increased by the absorption of visible light.

However, the oxide semiconductor layer including ZnO or ZnO is represented by an N-type semiconductor layer due to the oxygen vacancy, the Zn interstitial and the hydrogen incorporation, while an organic light-emitting display device is commonly realized with a P-type semiconductor layer. Also, in order to solve the problem about the change in data voltage due to the deterioration of the organic light emitting diode if the organic light-emitting display device is formed with the N-type semiconductor layer, there is proposed a method for forming an organic light-emitting display device using an organic light emitting diode having am inverted structure. The inverted organic light emitting diode is referred to as an organic light emitting diode in which a cathode electrode, a light emission layer and an anode electrode, which are all electrically connected, are sequentially formed on the thin film transistor formed on a substrate.

However, the contact characteristics between a cathode electrode and a light emission layer deteriorate, and the poor light emission layer is induced by an anode electrode formed on the light emission layer. That is to say, the contact characteristics between a cathode electrode composed of silver alloys (Ag alloy) and a light emission layer formed of organic materials deteriorate, and the light emission layer may be damaged if the anode electrode formed on the light emission layer, for example the anode electrode formed of ITO or IZO, is formed on the light emission layer using a sputtering method.

### SUMMARY OF THE INVENTION

Accordingly, the present invention is designed to solve such drawbacks of the prior art, and therefore an object of the present invention is to provide a thin film transistor including a P-type semiconductor layer, and an organic light-emitting display device having the thin film transistor.

One aspect of the present invention is achieved by providing a thin film transistor including a substrate, and a semiconductor layer, a gate electrode and a source/drain electrode formed on the substrate. The semiconductor layer includes a P-type ZnO:N layer through a reaction of a mono-nitrogen gas with a zinc precursor, and the ZnO:N layer includes an un-reacted impurity element at a content of 3 at % or less. The gate electrode is arranged on the substrate to be electrically coupled to the semiconductor layer. The source electrode and the drain electrode are arranged on the substrate for contacting portions of the semiconductor layer.

Another aspect of the present invention is achieved by providing a method for manufacturing a thin film transistor including steps of loading a substrate inside a chamber, supplying a zinc precursor and a mono-nitrogen reaction gas into the chamber, and purging the zinc precursor and the mono-nitrogen reaction gas supplied into the chamber. The zinc precursor and the mono-nitrogen reaction gas are absorbed into the substrate;

Still another aspect of the present invention is achieved by providing a method for manufacturing a thin film transistor using an atomic layer deposition method. The method includes steps of loading a substrate inside a chamber, injecting a zinc precursor inside the chamber to have the zinc precursor being chemically absorbed into the substrate, primarily purging the chamber, injecting a mono-nitrogen reaction gas into the chamber, and secondarily purging the chamber.

Yet another aspect of the present invention is achieved by providing an organic light-emitting display device including a substrate, a thin film transistor including a semiconductor layer, a gate electrode and a source/drain electrode formed on the substrate, and an organic light emitting diode formed on the thin film transistor. The organic light emitting diode is driven by the thin film transistor and produces light. The semiconductor layer includes a P-type ZnO:N layer through a reaction of a mono-nitrogen gas with a zinc precursor, and the ZnO:N layer includes an un-reacted impurity element at a content of 3 at % or less.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a cross-sectional view showing a thin film transistor including ZnO as a semiconductor layer.

FIG. 2 is a cross-sectional view showing a thin film transistor constructed as the first embodiment of the present invention.

FIG. 3 is a graph showing results obtained by measuring intensity of X-ray of a ZnO:N thin film of the present invention as a function binding energy using XPS.

FIGS. 4A to 4C are cross-sectional views showing processes for manufacturing the thin film transistor of the first embodiment of the present invention.

FIG. 5 is a cross-sectional view showing an organic light-emitting display device according to the first embodiment of the present invention.

FIG. 6 is a cross-sectional view showing a thin film transistor constructed as the second embodiment of the present invention.

FIGS. 7A to 7D are cross-sectional views showing processes for manufacturing the thin film transistor of the second embodiment of the present invention.

FIG. 8 is a cross-sectional view showing an organic light-emitting display device according to the second embodiment of the present invention.

### DETAILED DESCRIPTION OF THE INVENTION

Hereinafter, preferable embodiments of the thin film transistor and the organic light-emitting display device having the thin film transistor according to the present invention will be described with reference to the accompanying drawings. Here, when one element is connected to another element, one element may be not only directly connected to another element but also indirectly connected to another element via another element. Further, irrelative elements are omitted for clarity. Also, like reference numerals refer to like elements throughout.

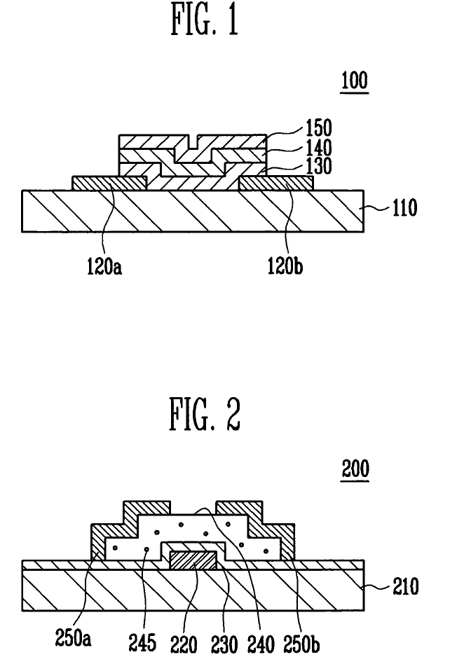

FIG. 1 is a cross-sectional view showing a thin film transistor including a semiconductor layer. Referring to FIG. 1, the thin film transistor 100 includes a source electrode 120a and a drain electrode 120b formed on a dielectric substrate 110, a semiconductor layer 130 arranged in contact with source and drain electrodes 120a and 120b, and a gate dielectric layer 140 and a gate electrode 150 laminated on the semiconductor layer 130.

FIG. 2 is a cross-sectional view showing a thin film transistor constructed as the first embodiment of the present invention. Referring to FIG. 2, the thin film transistor 200 of the present invention includes a gate electrode 220 formed on a substrate 210, a gate dielectric layer 230 formed on the substrate 210 covering the gate electrode 220, a semiconductor layer 240 including a channel region, a source region and a drain region and formed on the gate dielectric layer 230, and a source electrode 250a and a drain electrode 250b patterned on the semiconductor layer 240. The source electrode 250a is electrically coupled to the source region of the semiconductor layer 240, and the drain electrode 250b is electrically coupled to the drain region of the semiconductor layer 240. The semiconductor layer 240 is formed of P-type ZnO:N layers through a reaction of a mono-nitrogen gas with a zinc precursor including organic compounds, and the ZnO:N layer includes an impurity element 245 at a content of 3 at % (atomic percent) or less. The impurity element 245 can be carbon or halide.

The semiconductor layer 240 is composed of P-type semiconductors. The semiconductor layer 240 is formed of P-type ZnO:N layers by reacting a mono-nitrogen reaction gas with one inorganic precursor, namely one precursor including halide compounds and selected from the group consisting of ZnCl₂, ZnBr₂ and ZnF₂, or one organic compound precursor including carbon compounds and selected from the group consisting of DEZ (Diethyl-Zinc), DMZ (Dimethyl-Zinc) and EMZ (Ethyl-Methyl-Zinc).

Also, if oxygen is not present in the mono-nitrogen reaction gas, an oxygen source for supplementing oxygen may be further supplied. The mono-nitrogen reaction gas may be one selected from the group consisting of inorganic precursor compounds such as NO₂, NH₃, NO, NF₃, NCL₃, NI₃ and NBr₃, and the oxygen source may be one selected from the group consisting of H₂0 steam, O₂ gas and O₃.

For example, the semiconductor layer 240 may be formed of P-type ZnO:N layers by reacting the inorganic precursor ZnCl₂, the mono-nitrogen reaction gas NF₃ and the oxygen source H₂O as shown in Chemical Formula 1.

ZnCl₂+NF₃H₂O→ZnO:N+HCl,HF↑+Unreacted Residual Elements (Fₓ, Clₓ) Chemical Formula 1

As described above, the P-type ZnO:N semiconductor layer 240 is formed on the gate dielectric layer 230 by reacting the zinc precursor, the mono-nitrogen reaction gas and the oxygen source.

Meanwhile, the ZnO:N semiconductor layer 240 may include an halide at a content of 3 at % or less, since halides, namely ClX and FX elements, present in the inorganic precursor does not react with the nitrogen reaction gas and the oxygen source.

A source electrode 250a and a drain electrode 250b are formed on the source and drain region of the semiconductor layer 240. The source electrode 250a and the drain electrode 250b may be composed of conductive metal oxides such as, but is not limited to, aluminum (Al), aluminum alloy, silver (Ag), silver alloy, MoW, molybdenum (Mo), copper (Cu) or ITO, IZO, etc.

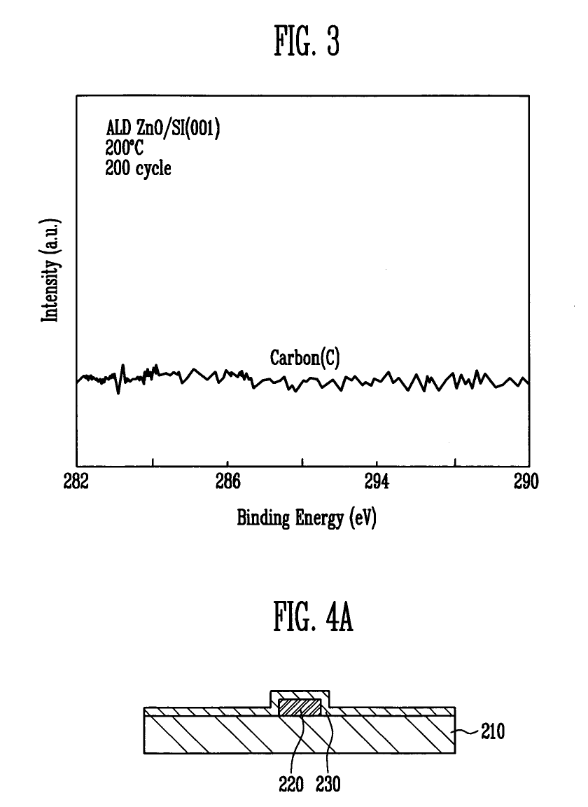

FIG. 3 is a graph showing results obtained by measuring intensity of X-ray of a ZnO:N thin film of the present invention as a function of binding energy using XPS (X-ray Photoelectron Spectroscopy). Referring to FIG. 3, the above measurement method is to detect a composition of the ZnO:N thin film formed using an atomic deposition method, and it may be seen that carbon is included in the ZnO:N thin film through the binding energy (eV) of X axis and the intensity of Y axis (a.u).

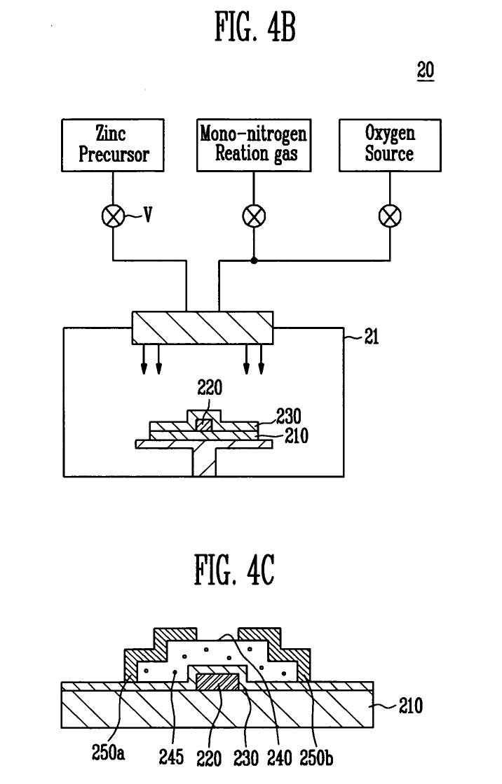

FIGS. 4A to 4C are cross-sectional views showing processes for manufacturing the thin film transistor according to the first embodiment of the present invention. Referring to FIGS. 4A to 4C, a gate electrode 220 is formed on the substrate 210, and then a gate dielectric layer 230 is formed on the front surface of the substrate 210 in a manner that the gate dielectric layer 230 covers the gate electrode 220.

The substrate 210 having the gate dielectric layer 230 formed therein is loaded into a chamber 21 of an atomic thin film formation device 20. If the substrate 210 therein is loaded into the chamber 21, a valve (V) is switched to inject a zinc precursor steam into the chamber 21, and thereby the zinc precursor is chemically absorbed into a surface of the substrate 210. At this time, residual materials which are not absorbed into the substrate 210 are discharged out of the chamber 21 through a primary purge process. Then, the mono-nitrogen gas is injected into the chamber 21 to react with the zinc precursor, and then un-reacted residual reaction by-products are discharged out of the chamber 21 through a secondary purge process. Also, when oxygen is not present in a mono-nitrogen reaction gas, an oxygen source for supplementing oxygen may be further supplied to the chamber 21.

Considering the above mentioned procedure as one cycle, a thin film is formed at a desired thickness by controlling the number of the cycles, and then if the thin film having a desired thickness is formed, a manufacture of the semiconductor layer 230 is completed without repeating additional cycles.

Accordingly, the semiconductor layer 230 having a thickness of a ZnO:N atomic layer unit is formed on the gate dielectric layer 230, and the halide as one of the un-reacted residual elements may be included in the semiconductor layer 230 at a content of 3 at % or less.

Accordingly, if the semiconductor layer is formed using the atomic deposition method, it is possible to accurately control a thickness of the thin film and to minimize a content of impurities in the semiconductor layer 230.

Then, a conductive metal is deposited onto the source and drain region of the semiconductor layer 240 and on the gate dielectric layer 230, and then patterned to form a source electrode 250a and a drain electrode 250b. The conductive metal for the source and drain electrodes can be selected from the group consisting of aluminum (Al), aluminum alloy, silver (Ag), silver alloy, MoW, molybdenum (Mo), copper (Cu) or ITO, IZO, etc.

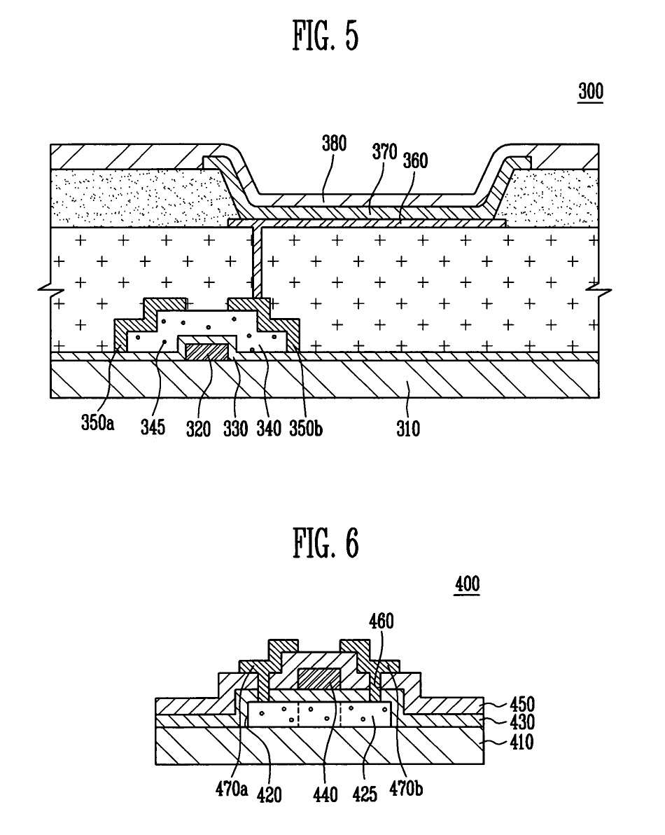

FIG. 5 is a cross-sectional view showing an organic light-emitting display device according to the first embodiment of the present invention. Referring to FIG. 5, the organic light-emitting display device 300 of the present invention includes a substrate 310, a thin film transistor including a semiconductor layer 340, a gate electrode 320 and a source/drain electrode 350a and 350b which are all formed on the substrate 310, and an organic light emitting diode formed on the thin film transistor and electrically connected with the thin film transistor. The semiconductor layer 340 is composed of P-type ZnO:N layers through a reaction of a mono-nitrogen gas with a zinc precursor including organic compounds, and the ZnO:N layer includes an impurity element 345 at a content of 3 at % or less. The impurity element 345 can be carbon or halide.

The thin film transistor formed on the substrate 310 has the same structure as in the thin film transistor of FIG. 2, and may be manufactured using the same method as shown in FIG. 4a to FIG. 4c.

The thin film transistor 300 includes a gate electrode 320 formed on the substrate 310, a gate dielectric layer 330 formed on the substrate 310 covering the gate electrode 320, a semiconductor layer 340 including a channel region, a source region and a drain region which are all formed on the gate dielectric layer 330, and a source electrode 350a and a drain electrode 350b patterned onto the semiconductor layer 340.

Meanwhile, the semiconductor layer 340 is composed of P-type semiconductors. The semiconductor layer 340 is formed of P-type ZnO:N layer by reacting a mono-nitrogen reaction gas with one inorganic precursor, namely one precursor including halide compounds and selected from the group consisting of ZnCl₂, ZnBr₂ and ZnF₂, or one organic compound precursor including carbon compounds and selected from the group consisting of DEZ (Diethyl-Zinc), DMZ (Dimethyl-Zinc) and EMZ (Ethyl-Methyl-Zinc). Also, if oxygen is not present in the mono-nitrogen reaction gas, an oxygen source for supplementing oxygen may be further supplied to the chamber. Also, the mono-nitrogen reaction gas may be one selected from the group consisting of inorganic precursor compounds such as NO₂, NH₃, NO, NF₃, NCL₃, NI₃ and NBr₃, and the oxygen source may be formed of one selected from the group consisting of H₂0 steam, O₂ gas and O₃.

For example, the semiconductor layer 340 may react with the inorganic precursor ZnCl₂, the mono-nitrogen reaction gas NF₃ and the oxygen source H₂O to form a P-type ZnO:N layer as presented in Chemical Formula 2.

ZnCl₂+NF₃H₂O→ZnO:N+HC,HF↑+Unreacted Residual Elements (Fₓ, Clₓ) Chemical Formula 2

As described above, a P-type ZnO:N semiconductor layer 340 is formed on the gate dielectric layer 330 by reacting the zinc precursor with the mono-nitrogen reaction gas and the oxygen source.

Meanwhile, the ZnO:N semiconductor layer 340 may include an halide at a content of 3 at % or less, since halides, namely Cl₂, Br₂ and F₂, present in the inorganic precursor does not react with the nitrogen reaction gas and the oxygen source.

An organic light emitting diode electrically connected with the thin film transistor is formed on the thin film transistor. The organic light emitting diode includes an anode electrode 360, a light emission layer 370, and a cathode electrode 380, which are all patterned according to the pixel region.

The anode electrode 360 is electrically connected with a drain electrode 350b of the thin film transistor through a via hole. The anode electrode 360 is patterned into a shape of the pixel region through a photolithographic process, etc. The shape of the pixel region is defined by a pixel definition layer.

A light emission layer 370 is formed on the anode electrode 360, and the light emission layer 370 may include an electron injection layer, an electron transport layer, a hole injection layer, and an electron transport layer. A cathode electrode 380 is formed on the light emission layer 370.

In this organic light emitting diode, if a predetermined voltage is applied to the anode electrode 360 and the cathode electrode 380, then holes injected from the anode electrode 360 are transferred to the light emission layer 370 via the hole transport layer constituting the light emission layer 370, and electrons injected from the cathode electrode 380 is injected into the light emission layer 370 via the electron transport layer. At this time, the electrons and the holes are re-combined in the light emission layer 370 to generate exitons, and the resultant exitons are excited and decays into a ground state, and therefore fluorescent molecules of the light emission layer 370 emit light to display an image.

As described above, the organic light-emitting display device 300 employs a normal (not inverted) organic light emitting diode, since the N-type zinc oxide semiconductor layer is formed of P-type ZnO:N layers. Therefore, the deterioration in the contact characteristics between the cathode electrode and the light emission layer may be prevented. The deterioration in the contact characteristics being generated in the organic light emitting diode having an inverted structure and the damage of the light emission layer may be also prevented.

In addition, the organic light-emitting display device 300 is formed of P-type ZnO:N layers, and therefore the present invention may provide an organic light emitting diode having a lower operation voltage and an excellent light-emitting efficiency.

FIG. 6 is a cross-sectional view showing a thin film transistor constructed as the second embodiment of the present invention. Referring to FIG. 6, the thin film transistor 400 of to the present invention includes a substrate 410, and a semiconductor layer 420, a gate electrode 440 and source/drain electrodes 470a and 470b formed on the substrate 410. The semiconductor layer 420 is composed of P-type ZnO:N layers 420 through a reaction of a mono-nitrogen gas with a zinc precursor including halide compounds, and the ZnO:N layer 420 includes an halide 425 at a content of 3 at % or less.

The semiconductor layer 420 is composed of P-type semiconductors. The semiconductor layer 420 is formed of P-type ZnO:N layers by reacting a mono-nitrogen reaction gas with a zinc precursor, namely one organic compound precursor including carbon compounds and selected from the group consisting of DEZ (Diethyl-Zinc), DMZ (Dimethyl-Zinc) and EMZ (Ethyl-Methyl-Zinc), or one inorganic precursor, namely one precursor including halide compounds and selected from the group consisting of ZnCl₂, ZnBr₂ and ZnF₂. Also, if oxygen is not present in the mono-nitrogen reaction gas, an oxygen source for supplementing oxygen may be further supplied to the chamber. The mono-nitrogen reaction gas may be one selected from the group consisting of NO₂, NH₃, NO, NF₃, NCL₃, NI₃ and NBr₃, and the oxygen source may be formed of one selected from the group consisting of H₂0 steam, O₂ gas and O₃.

For example, the semiconductor layer 420 may be formed of P-type ZnO:N layers by reacting the organic compound precursor DEZ (Diethyl-Zinc) and the mono-nitrogen gas NO₂ as shown in Chemical Formula 3.

DEZ+NO₂→ZnO:N+C₂H₅OHetc↑+Possible Residual Elements in Thin Film (C) Chemical Formula 3

As described above, a P-type ZnO:N semiconductor layer 420 is formed on the substrate 210 by reacting a mono-nitrogen reaction gas with a zinc precursor. Also, C₂H₅OHetc means that hydrocarbon in addition to ethanol may be generated. Meanwhile, the ZnO:N semiconductor layer 420 may include an carbon, which is one of the un-reacted residual elements, at a content of 3 at % or less, since diethyl, dimethyl and ethyl, which are present in the organic compound precursor including carbon compounds, do not react with the nitrogen reaction gas.

A source electrode 470a and a drain electrode 470b are patterned onto a doping region and an interlayer dielectric layer 450. The source electrode 470a and the drain electrode 470b may be composed of conductive metal oxides such as, but is not limited to, aluminum (Al), aluminum alloy, silver (Ag), silver alloy, MoW, molybdenum (Mo), copper (Cu) or ITO, IZO, etc.

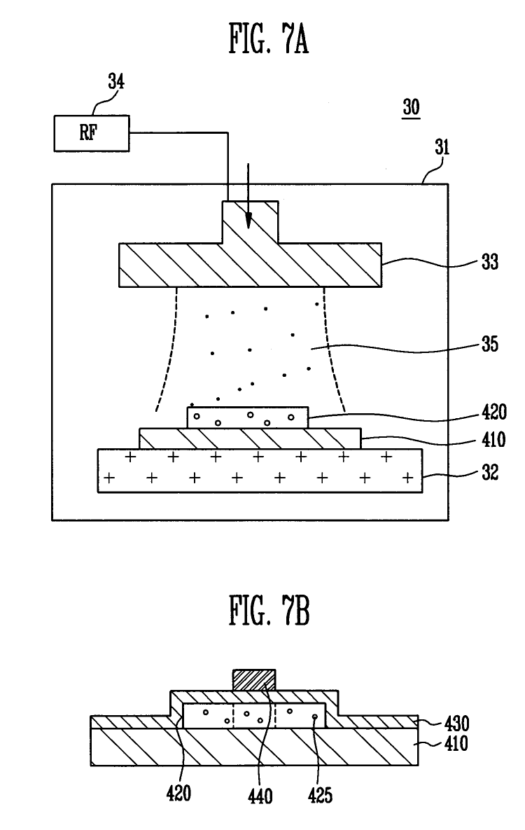

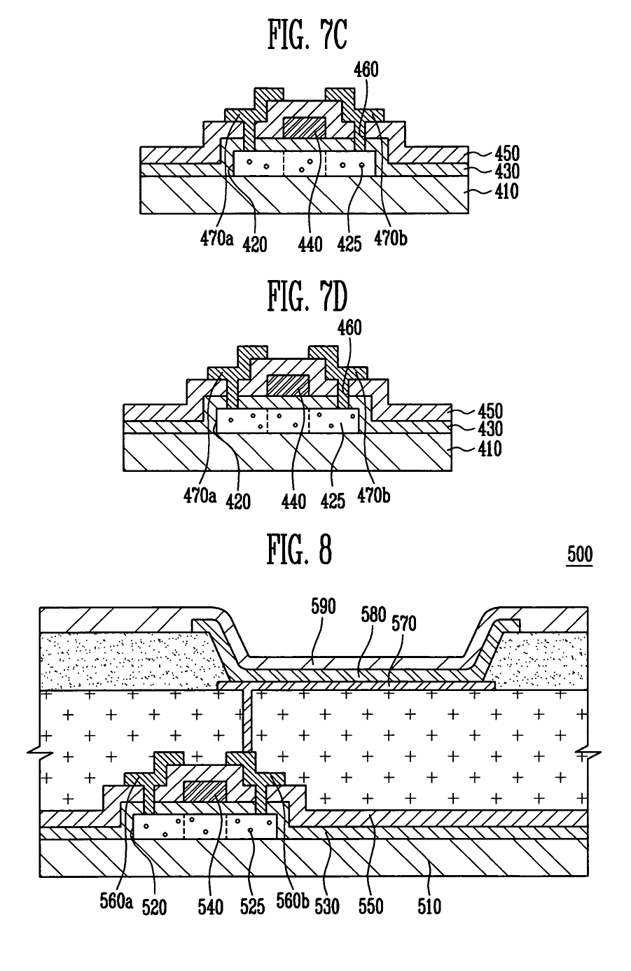

FIGS. 7A to 7D are cross-sectional views showing processes for manufacturing the thin film transistor according to the second embodiment of the present invention. Referring to FIG. 7A to FIG. 7D, a semiconductor layer 420 including a channel region, a source region and a drain region is formed on the substrate 410.

In order to form a semiconductor layer 420, the substrate 410 is loaded into a chamber 31 of a plasma chemical vapor deposition apparatus 30. The plasma chemical vapor deposition apparatus 30 includes a chamber 31 in which a reaction occurs, and a stage heater 32 on which the substrate 410 is safely arranged, and a shower head 33. The shower head 33 is installed in a position facing a surface of the stage heater 32 in which the substrate 410 is safely arranged. A RF power is connected to the shower head 33 to convert a reaction gas, supplied through the shower head 33, into a plasma state.

A semiconductor layer 420 is formed on the substrate 410 using the plasma chemical vapor deposition apparatus 30. The plasma chemical vapor deposition method of the present invention is described as follows.

The substrate 410 is safely arranged on the stage heater 32, and then the organic compound precursor gas including carbon compounds and the mono-nitrogen reaction gas 34 are supplied onto the substrate 410 through the shower head 33 at the same time when a high-frequency power source (RF:34) is applied. The organic compound precursor gas and the mono-nitrogen gas become a plasma gas state 35 through the shower head 33, and a ZnO:N semiconductor layer 420 is formed on the substrate 410 through the reaction of the plasma gases. Meanwhile, carbon which is one of the un-reacted residual elements may be present in a content of 3 at % or less in the ZnO:N semiconductor layer 420.

A gate dielectric layer 430 is formed in the front surface of the substrate 410 covering the semiconductor layer 420. A gate electrode 440 is formed on a gate dielectric layer 430 corresponding to a channel region of the semiconductor layer 420. An interlayer dielectric layer 450 is formed on the gate dielectric layer 430 covering the gate electrode 440. In order to connect a source region of the semiconductor layer 420 with a drain region and a drain electrode 470b of the source electrode 470a and the semiconductor layer 420, a contact hole 460 is formed in the gate dielectric layer 430 and the interlayer dielectric layer 450.

A conductive metal oxide is deposited onto the interlayer dielectric layer 450 and the contact hole 460 to form a source electrode 470a and a drain electrode 470b. The conductive metal oxide can be selected from the group consisting of aluminum (Al), aluminum alloy, silver (Ag), silver alloy, MoW, molybdenum (Mo), copper (Cu) or ITO, IZO, etc. The source electrode 470a and the drain electrode 470b are electrically connected with source and drain regions of the semiconductor layer 420 through the contact hole 460.

FIG. 8 is a cross-sectional view showing an organic light-emitting display device according to the second embodiment of the present invention. Referring to FIG. 8, the organic light-emitting display device 500 of the present invention includes a substrate 510, a thin film transistor including a semiconductor layer 520, a gate electrode 540 and a source/drain electrode 560a and 560b which are all formed on the substrate 510, and an organic light emitting diode formed on the thin film transistor and electrically connected with the thin film transistor. The semiconductor layer 520 is composed of P-type ZnO:N layers 520 through a reaction of a mono-nitrogen gas with a zinc precursor including organic compounds, and the ZnO:N layer 520 includes an carbon 525 at a content of 3 at % or less.

The thin film transistor formed on the substrate 510 has the same structure as in the thin film transistor of FIG. 6, and may be manufactured using the same method as shown in FIG. 7a to FIG. 7d.

The thin film transistor includes a semiconductor layer 520 including a channel region, a source region and a drain region which are all formed on the substrate 510, a gate dielectric layer 530 formed on the semiconductor layer 520, a gate electrode 540 formed on the gate dielectric layer 530 corresponding to a channel region of the semiconductor layer 520, an interlayer dielectric layer 550 formed in the front surface of the gate dielectric layer 530 including the gate electrode 540, a source electrode 560a and a drain electrode 560b connected with a source region and a drain region of the semiconductor layer 520 through the contact hole 560 formed in the gate dielectric layer 530 and the interlayer dielectric layer 550.

The semiconductor layer 520 is composed of P-type semiconductors. The semiconductor layer 520 is formed of P-type ZnO:N layers by reacting a mono-nitrogen reaction gas with a zinc precursor, namely one organic compound precursor including carbon compounds and selected from the group consisting of DEZ (Diethyl-Zinc), DMZ (Dimethyl-Zinc) and EMZ (Ethyl-Methyl-Zinc), or one inorganic precursor, namely one precursor including halide compounds and selected from the group consisting of ZnCl₂, ZnBr₂ and ZnF₂. Also, if oxygen is not present in the mono-nitrogen reaction gas, an oxygen source for supplementing oxygen may be further supplied to the chamber. The mono-nitrogen reaction gas may be one selected from the group consisting of NO₂, NH₃, NO, NF₃, NCL₃, NI₃ and NBr₃, and the oxygen source may be formed of one selected from the group consisting of H₂0 steam, O₂ gas and O₃.

For example, the semiconductor layer 540 may be formed of P-type ZnO:N layers by reacting the organic compound precursor DEZ (Diethyl-Zinc) and the mono-nitrogen gas NO₂ as shown in Chemical Formula 4.

DEZ+NO₂→ZnO:N+C₂H₅OHetc↑+Possible Residual Elements in Thin Film (C) Chemical Formula 4

As described above, a P-type ZnO:N semiconductor layer 520 is formed on the substrate 510 by reacting a mono-nitrogen reaction gas with a zinc precursor. Also, C₂H₅OHetc means that hydrocarbon in addition to ethanol may be generated. Meanwhile, the ZnO:N semiconductor layer 520 may include an carbon, which is one of the un-reacted residual elements, at a content of 3 at % or less since diethyl, dimethyl and ethyl, which are present in the organic compound precursor including carbon compounds, do not react with the nitrogen reaction gas.

An organic light emitting diode electrically connected with the thin film transistor is formed on the thin film transistor. The organic light emitting diode includes an anode electrode 570, a light emission layer 580 and a cathode electrode 590 which are patterned along the pixel region.

The anode electrode 570 is electrically connected with a drain electrode 560b of the thin film transistor through a via hole. The anode electrode 570 is patterned into a shape of the pixel region through a photolithographic process, etc. The shape of the pixel region is defined by the pixel definition layer.

A light emission layer 580 is formed on the anode electrode 570, and the light emission layer 580 may include an electron injection layer, an electron transport layer, a hole injection layer and an electron transport layer. A cathode electrode 590 is formed on the light emission layer 580.

In this organic light emitting diode, if a predetermined voltage is applied to the anode electrode 570 and the cathode electrode 590, then holes injected from the anode electrode 570 are transferred to the light emission layer 580 via the hole transport layer constituting the light emission layer 580, and electrons injected from the cathode electrode 590 is injected into the light emission layer 580 via the electron transport layer. At this time, the electrons and the holes are re-combined in the light emission layer 580 to generate exitons, and the resultant exitons are excited and decays into a ground state, and therefore fluorescent molecules of the light emission layer 580 emit light to display an image.

As described above, the organic light-emitting display device 500 employs a normal organic light emitting diode, since the N-type zinc oxide semiconductor layer is formed of P-type ZnO:N layers. Therefore, the deterioration in the contact characteristics between the cathode electrode and the light emission layer may be prevented. The deterioration in the contact characteristics being generated in the organic light emitting diode having an inverted structure and the damage of the light emission layer may be also prevented.

In addition, the organic light-emitting display device 500 is formed of P-type ZnO:N layers, and therefore the present invention may provide an organic light emitting diode having a lower operation voltage and an excellent light-emitting efficiency.

As described above, according to the present invention, the thin film transistor having the P-type semiconductor layer, and the organic light-emitting display device may be easily driven by forming a semiconductor layer including P-type ZnO:N through the reaction of a mono-nitrogen gas with a zinc precursor.

The description proposed herein is just a preferable example for the purpose of illustrations only, not intended to limit the scope of the invention, so it should be understood that other equivalents and modifications could be made thereto without departing from the spirit and scope of the invention as apparent to those skilled in the art. For example, the top gate (coplanar) structure and the bottom gate (inverse staggered) structure of the thin film transistor, and the manufacturing method thereof have been described in the above-mentioned embodiments, but it is understood that a P-type ZnO:N semiconductor layer may be formed in the same manner as in the staggered structure, as apparent to those skilled in the art.

As described above, the preferred embodiments of the present invention have been described in detail. Therefore, it should be understood that the present invention might be not defined within the scope of which is described in detailed description but within the scope of which is defined in the claims and their equivalents.

What is claimed is:

1. A thin film transistor comprising:
a substrate;
a semiconductor layer arranged on the substrate, the semiconductor layer including a P-type ZnO:N layer through a reaction of a mono-nitrogen gas with a zinc precursor, the ZnO:N layer including an un-reacted impurity element at a content of 3 at % or less;
a gate electrode arranged on the substrate; and
a source electrode and a drain electrode, each of which is arranged on the substrate for contacting a portion of the semiconductor layer.

2. The thin film transistor according to claim 1, wherein the zinc precursor includes an organic compound precursor including carbon compounds, and is selected from the group consisting of DEZ (Diethyl-Zinc), DMZ (Dimethyl-Zinc) and EMZ (Ethyl-Methyl-Zinc).

3. The thin film transistor according to claim 2, wherein the un-reacted impurity element includes carbon.

4. The thin film transistor according to claim 1, wherein the zinc precursor includes an inorganic precursor including halide compound, and is selected from the group consisting of ZnCl₂, ZnBr₂ and ZnF₂.

5. The thin film transistor according to claim 4, wherein the un-reacted impurity element includes halide.

6. The thin film transistor according to claim 1, wherein the semiconductor layer further includes an oxygen source.

7. A method for manufacturing a thin film transistor using an atomic layer deposition method, the method comprising:
loading a substrate inside a chamber;
injecting a zinc precursor inside the chamber to have the zinc precursor being chemically absorbed into the substrate;
primarily purging the chamber;
injecting a mono-nitrogen reaction gas inside the chamber; and
secondarily purging the chamber.

8. The method according to claim 7, further comprising a step of supplying an oxygen source inside the chamber.

9. The method according to claim 8, wherein the oxygen source is selected from the group consisting of H₂O steam, O₂ gas, and O₃.

10. The method according to claim 7, wherein the zinc precursor includes an organic compound precursor, and is selected from the group consisting of DEZ (Diethyl-Zinc), DMZ (Dimethyl-Zinc), and EMZ (Ethyl-Methyl-Zinc).

11. The method according to claim 7, wherein the zinc precursor includes an inorganic precursor including halide compound, and is selected from the group consisting of ZnCl₂, ZnBr₂, and ZnF₂.

12. The method according to claim 7, wherein the mono-nitrogen reaction gas is selected from the group consisting of NO₂, NH₃, NO, NF₃, NCL₃, NI₃, and NBr₃.

13. A method for manufacturing a thin film transistor using a plasma chemical vapor deposition method, the method comprising:
loading a substrate inside a chamber; and
supplying a zinc precursor gas and a mono-nitrogen reaction gas onto the substrate to form a P-type ZnO:N semiconductor layer on the substrate through the plasma reaction.

14. The method according to claim 13, further comprising a step of supplying an oxygen source inside the chamber.

15. The method according to claim 14, wherein the oxygen source is selected from the group consisting of H₂O steam, O₂ gas, and O₃.

16. The method according to claim 13, wherein the zinc precursor gas includes an organic compound precursor, and is selected from the group consisting of DEZ (Diethyl-Zinc), DMZ (Dimethyl-Zinc), and EMZ (Ethyl-Methyl-Zinc).

17. The method according to claim 13, wherein the zinc precursor gas includes an inorganic precursor including halide compound, and is selected from the group consisting of ZnCl₂, ZnBr₂, and ZnF₂.

18. The method according to claim 13, wherein the nitrogen reaction gas is selected from the group consisting of NO₂, NH₃, NO, NF₃, NCL₃, NI₃, and NBr₃.

19. An organic light-emitting display device, comprising:
a substrate,
a thin film transistor comprising:
a semiconductor layer arranged on the substrate, the semiconductor layer including a P type ZnO:N layer through a reaction of a mono nitrogen gas with a zinc precursor, the ZnO:N layer including an un-reacted impurity element at a content of 3 at % or less;
a gate electrode arranged on the substrate; and
a source electrode and a drain electrode, each of which is arranged on the substrate for contacting a portion of the semiconductor layer; and
an organic light emitting diode formed on the thin film transistor, the organic light emitting diode being driven by the thin film transistor and producing light.
